(19) United States
(12) Patent Application Publication
(10) Pub. No.: US 2023/0108072 A1
(43) Pub. Date: Apr. 6, 2023

(54) GALLIUM NITRIDE TRANSISTORS WITH RELIABILITY ENHANCEMENTS

(71) Applicant: Intel Corporation, Santa Clara, CA (US)

(72) Inventors: Han Wui Then, Portland, OR (US); Paul Fischer, Portland, OR (US); Marko Radosavljevic, Portland, OR (US)

(73) Assignee: Intel Corporation, Santa Clara, CA (US)

(21) Appl. No.: 17/481,917

(22) Filed: Sep. 22, 2021

(51) Int. Cl. H01L 29/778; H01L 29/47; H01L 29/423; H01L 23/522; H01L 23/532; H01L 29/66; H01L 29/40

(52) U.S. Cl. CPC H01L 29/7786; H01L 23/5226; H01L 23/5228; H01L 23/53257; H01L 29/401; H01L 29/475; H01L 29/42316; H01L 29/66462; H01L 29/2003

(57) ABSTRACT

In one embodiment, an apparatus includes a source region, a drain region, a channel between the source and drain regions, and a polarization layer on the channel. The channel includes gallium and nitrogen, and the polarization layer includes a group III-nitride (III-N) material. The apparatus further includes a gate structure having a first region and a second region. The first region extends into the polarization layer and includes a metal. The second region is coupled to the first region and includes a polycrystalline semiconductor material.

### BACKGROUND

Gallium nitride (GaN) is a group III-V semiconductor that has several advantages over silicon (Si). For example, GaN has a direct and wide band gap, high breakdown field, high electron mobility, thermal stability (e.g., a high melting point), and the ability to form a high-mobility two-dimensional electron gas (2DEG) when deposited on another III-V semiconductor. As a result, GaN transistors are particularly beneficial for high-power and high-frequency electronic devices that operate at high temperatures.

However, GaN transistors—whether in the form of a MOS or Schottky transistor— also suffer from bias temperature instability (BTI), which causes the threshold voltage to shift over time due to stress from applied voltage. For example, when applying a gate bias at a high temperature (e.g., 80-90° C.), the threshold voltage of the transistor shifts over time, which may eventually lead to a device failure.

### BRIEF DESCRIPTION OF THE DRAWINGS

FIG. 1 illustrates an example of a gallium nitride (GaN) Schottky transistor with a polycrystalline gate resistor in accordance with certain embodiments.

FIG. 2 illustrates a circuit diagram for a GaN Schottky transistor with a polycrystalline gate resistor.

FIG. 3 illustrates a graph of the bias temperature instability (BTI) degradation for GaN Schottky transistors with and without a polycrystalline gate resistor.

FIG. 4 illustrates a flowchart for fabricating a group III-nitride (III-N) Schottky transistor with a polycrystalline gate resistor in accordance with certain embodiments.

FIGS. 5A-B illustrate examples of a gallium nitride (GaN) metal-oxide-semiconductor (MOS) transistor with a charge-gettering gate dielectric in accordance with certain embodiments.

FIGS. 6A-B illustrate graphs of the voltage flat band (VFB) for a GaN MOS transistor with a charge-gettering gate dielectric when the charge is switched in and out.

FIG. 7 illustrates a flowchart for fabricating a group III-nitride (III-N) metal-oxide-semiconductor (MOS) transistor with a charge-gettering gate dielectric in accordance with certain embodiments.

FIG. 8 illustrates a block diagram of an example electrical device that may include one or more embodiments of the disclosure.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly, in accordance with any of the embodiments disclosed herein.

FIG. 11 is a cross-sectional side view of an integrated circuit device assembly that may include a microelectronic assembly, in accordance with any of the embodiments disclosed herein.

### DETAILED DESCRIPTION

Gallium nitride (GaN) is a group III-V semiconductor that has several advantages over silicon (Si). For example, GaN has a direct and wide band gap, high breakdown field, high electron mobility, thermal stability (e.g., a high melting point), and the ability to form a high-mobility two-dimensional electron gas (2DEG) when deposited on another III-V semiconductor. As a result, GaN transistors are particularly beneficial for high-power and high-frequency electronic devices that operate at high temperatures.

However, GaN transistors—whether in the form of a MOS or Schottky transistor— also suffer from bias temperature instability (BTI), which causes the threshold voltage to shift over time due to stress from applied voltage. For example, when applying a gate bias at a high temperature (e.g., 80-90° C.), the threshold voltage of the transistor shifts over time, which may eventually lead to a device failure. Thus, for purposes of product commercialization, it is crucial to minimize the BTI degradation over the lifetime of a product. Accordingly, there is a need to improve the BTI degradation for GaN transistors.

Accordingly, this disclosure presents various embodiments of GaN transistors designed to reduce BTI degradation. For example, this disclosure presents embodiments of a GaN Schottky transistor with a poly-gate resistor designed to reduce the effects of BTI. In addition, this disclosure presents embodiments of a GaN MOS transistor with a gate dielectric designed to neutralize the effects from trapped charges that cause BTI. These embodiments provide numerous advantages, including longer and more predictable product lifetimes, which enables designers to design more reliable products with higher performance.

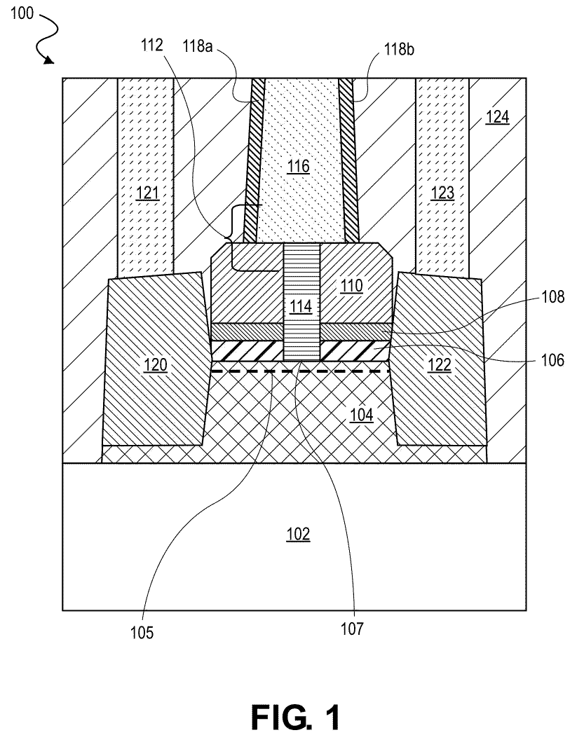

FIG. 1 illustrates an example embodiment of a gallium nitride (GaN) Schottky transistor 100 with a polycrystalline gate resistor in accordance with certain embodiments. In the illustrated embodiment, for example, transistor 100 includes a T-gate 112 formed with a polycrystalline gate resistor 116 in the upper portion of the gate and a gate electrode 114 in the lower portion of the gate. In this manner, current from the supply voltage source flows through the gate resistor 116 before flowing through the gate electrode 114, which helps reduce BTI degradation in the transistor 100.

In the illustrated embodiment, transistor 100 includes a buffer layer 102, a transistor channel 104, source and drain regions 120, 122, source and drain contacts 121, 123, a polarization layer 106, a passivation layer 108, a diffusion protection layer (DPL) 110, a gate 112, and an inter-layer dielectric (ILD) 124.

The buffer layer 102, which may be formed on or above a silicon substrate (not shown), may include a group III-nitride (III-N) material, such as aluminum gallium nitride (AlGaN). The transistor channel 104 is formed on or above the buffer layer and may also include a III-N material, such as gallium nitride (GaN). In this manner, the AlGaN buffer layer 102 is between the GaN channel 104 and the Si substrate and serves as a buffer separating those layers.

The source region 120 and the drain region 122 are formed on opposite ends of the channel 104, such that they are coupled together via the channel 104. Moreover, the source and drain regions 120, 122 may be formed from a III-N material, such as indium gallium nitride (e.g., N+ InₓGa₁₋ₓN, where x is between 0 and 0.3 and the dopant is Si).

The source and drain contacts 121, 123 are formed on or above above—and in contact with—the respective source and drain regions 120, 122. Moreover, the source and drain contacts 121, 123 may include an electrically conductive material, such as a metal.

The polarization layer 106 is formed on or above the GaN channel 104 and may include a III-N material, such as aluminum gallium nitride (AlGaN). The function of the polarization layer 106 is to induce the formation of a two-dimensional electron gas (2DEG) 105. For example, when the AlGaN polarization layer 106 is deposited on the GaN channel 104, a two-dimensional electron gas (2DEG) 105 forms at or near the interface of the channel 104 and the polarization layer 106.

The passivation layer 108 is formed on or above the polarization layer 106 and may include a dielectric material such as silicon dioxide (SiO₂) or silicon nitride (SiN). The function of the passivation layer 108 is to passivate the surface of the polarization layer 106 (e.g., to protect it from contamination).

The diffusion protection layer (DPL) 110 is formed on or above the passivation layer 108 and may include a dielectric or insulating material, such as silicon nitride (SiN) or silicon dioxide (SiO₂). The function of the DPL 110 is to provide protection from diffusion current caused by the diffusion of charge carriers.

The gate 112 includes a poly-gate resistor 116 in series with a gate electrode 114. For example, the gate 112 is formed as a T-gate—or a gate whose shape resembles the letter “T” with an upper portion that is wider than a lower portion—where the upper portion includes a polycrystalline gate resistor 116 and the lower portion includes a gate electrode 114.

The gate electrode 114 may include any work function metal, such as titanium nitride (TiN). Moreover, the gate electrode 114 extends through the diffusion protection layer (DPL) 110 and passivation layer 108 and into the polarization layer 106. In this manner, since the metal gate electrode 114 extends into the AlGaN polarization layer 106, a Schottky barrier 107 is formed at or near an interface of the gate electrode 114 and the polarization layer 106.

The polycrystalline gate resistor 116 may include a polycrystalline semiconductor material, such as polycrystalline silicon (poly-Si) (doped n and p) or polycrystalline gallium nitride (poly-GaN) (doped n and p). Moreover, the gate resistor 116 extends in the opposite direction as the gate electrode 114, where it is coupled to a supply voltage (not shown).

In some embodiments, a pair of gate sidewall spacers 118a,b may also be formed on opposing sides of the gate resistor 116. The gate spacers 118a,b may include any suitable dielectric material, such as silicon nitride (SiN) and/or silicon carbon nitride (SiCN).

In this manner, current from the supply voltage source flows through the gate resistor 116 before flowing through the gate electrode 114, which helps reduce BTI degradation in the transistor 100. For example, the forward gate current (I_{G}) of the Schottky transistor 100 is xtor clamped by the poly-gate resistor 116 and does not scale with xtor width. Thus, the BTI degradation in the Schottky junction 107 is mitigated by the resistor 116 at the gate 112. The gate current plays a key role in compensating for BTI degradation in the Schottky junction 107. For example, as the threshold voltage drifts higher with stress, the gate current (I_{G}) reduces and the gate voltage (V_{G}) is compensated by a drop of I_{G}*R in the resistor 116 in series with the Schottky junction 107 (where R represents the resistance of the poly-gate resistor 116).

The inter-layer dielectric (ILD) 124 is used to fill the remaining gaps or areas of the transistor 100, and may include any suitable dielectric material, such as silicon dioxide (SiO₂).

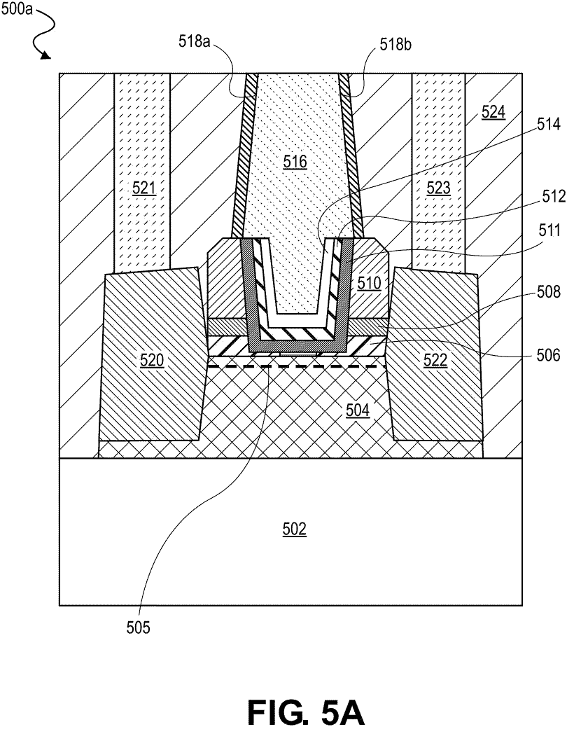

In some embodiments, certain layers of the transistor 100 may be omitted, added, or rearranged. Moreover, certain layers may be formed using materials other than those described above, including the materials described in the example fabrication process 400 of FIG. 4 and in other sections of this disclosure.

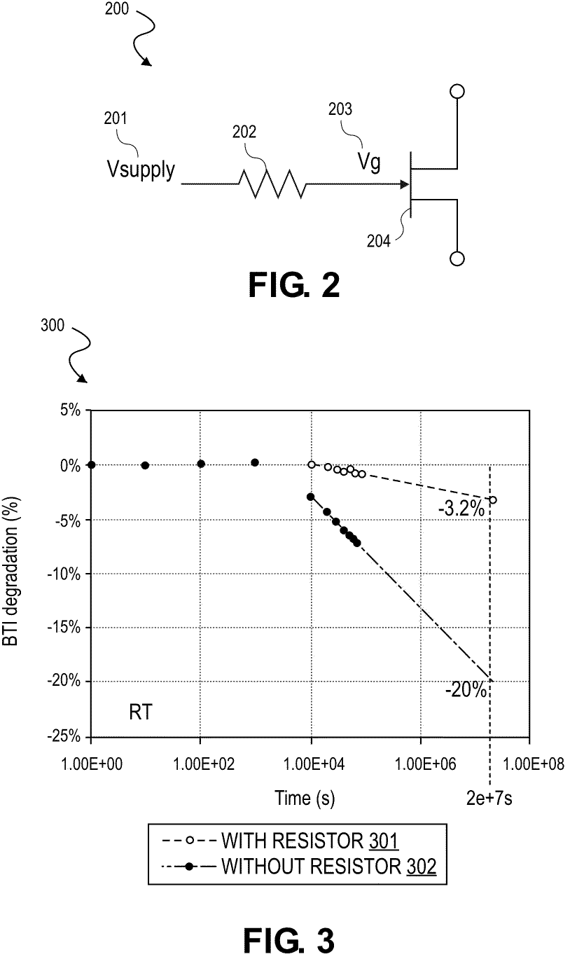

FIG. 2 illustrates the equivalent circuit diagram 200 for the GaN Schottky transistor 100 of FIG. 1. As shown in circuit 200, the supply voltage source (V_{supply}) 201 feeds into the gate resistor 202 before the GaN transistor 204, which decreases the gate voltage (V_{g}) 203 applied at the GaN transistor 204 and thus improves the BTI degradation.

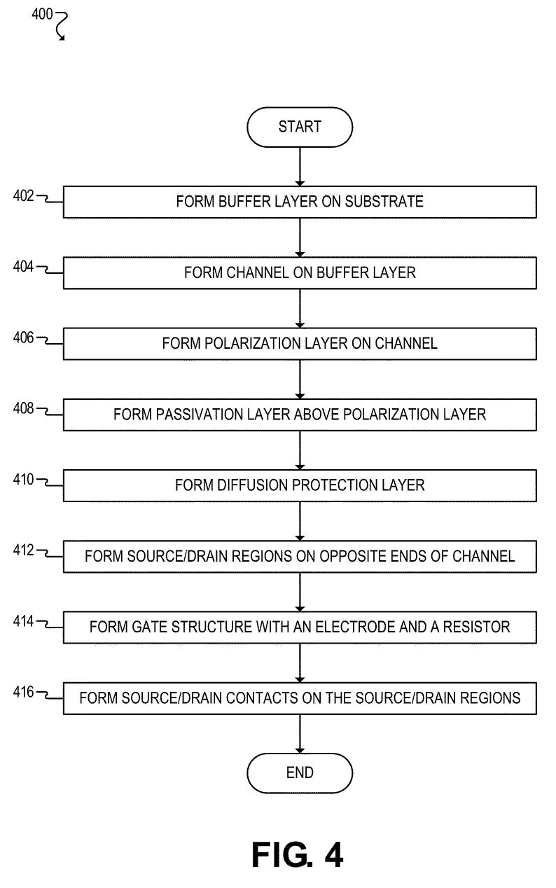

FIG. 3 illustrates a graph 300 of the bias temperature instability (BTI) degradation for GaN Schottky transistors with 301 and without 302 a polycrystalline gate resistor. As shown in graph 300, the GaN transistor with the poly-gate resistor 301 has significantly less BTI degradation than the GaN transistor without a gate resistor 302 (e.g., -3.2% vs. -20%).

FIG. 4 illustrates a flowchart 400 for fabricating a group III-nitride (III-N) Schottky transistor with a polycrystalline gate resistor in accordance with certain embodiments. In some embodiments, for example, flowchart 400 may be used to fabricate the gallium nitride (GaN) Schottky poly-gate transistor 100 of FIG. 1. It will be appreciated in light of the present disclosure, however, that flowchart 400 is only one example methodology for arriving at the example III-N Schottky transistors shown and described throughout this disclosure.

The steps of flowchart 400 may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metalorganic chemical vapor deposition (MOCVD), molecular beam epitaxy (MBE) atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The flowchart begins at block 402 by forming a buffer layer on a substrate. In some embodiments, the substrate may be formed from a material that includes silicon (Si), and the buffer layer may be formed from a group III-nitride (III-N) material. For example, the III-N material may include aluminum (Al), gallium (Ga), and/or nitrogen (N), such as aluminum gallium nitride (AlGaN), among other examples.

The flowchart then proceeds to block 404 to form a channel on the buffer layer. In some embodiments, the channel may be formed from a III-N material. For example, the III-N material may include gallium (Ga) and/or nitrogen (N), such as gallium nitride (GaN), among other examples. In this manner, the channel and the substrate are separated by the buffer layer, and thus the buffer layer serves as a buffer between the channel and the substrate.

The flowchart then proceeds to block 406 to form a polarization layer on the channel. In some embodiments, the polarization layer may be formed from a III-N material. For example, the III-N material may include aluminum (Al), gallium (Ga), and/or nitrogen (N), such as aluminum gallium nitride (AlGaN), among other examples. In this manner, since the polarization layer and channel are both III-N materials, when the polarization layer is deposited on the channel, a two-dimensional electron gas (2DEG) forms at or near the interface of the channel and the polarization layer.

The flowchart then proceeds to block 408 to form a passivation layer on or above the polarization layer. In some embodiments, the passivation layer may be formed from a material that includes silicon (Si), oxygen (O), and/or nitrogen (N), such as silicon dioxide (SiO₂) or silicon nitride (SiN), among other examples. In this manner, by forming the passivation layer on the polarization layer, the passivation layer passivates the surface of the polarization layer.

The flowchart then proceeds to block 410 to form a diffusion protection layer (DPL) (e.g., a dielectric layer) on or above the passivation layer. In some embodiments, the DPL may be formed from a dielectric or insulating material. For example, the DPL may be formed from a material that includes silicon (Si), nitrogen (N), and/or oxygen (O), such as silicon dioxide (SiO₂) or silicon nitride (SiN), among other examples.

The flowchart then proceeds to block 412 to form source and drain regions on opposite ends of the channel. For example, the source region is formed adjacent to one end of the channel, and the drain region is formed adjacent to another end of the channel. In this manner, the source and drain regions are coupled via the channel. In some embodiments, the source and/or drain regions may be formed from a material that includes indium (In), gallium (Ga), and/or nitrogen (N), such as indium gallium nitride (e.g., N+ InₓGa₁₋ₓN, where x is between 0 and 0.3 and the dopant is Si), among other examples.

The flowchart then proceeds to block 414 to form a gate structure that includes both an electrode and a resistor. In some embodiments, for example, the gate structure may be formed as a T-gate (e.g., a gate having a shape that resembles the letter “T”), which includes a lower portion for the gate electrode and an upper portion for the gate resistor (e.g., where the upper portion is wider than the lower portion). The gate electrode extends through the diffusion protection layer (DPL) (e.g., dielectric layer) and passivation layer and into the polarization layer, while the gate resistor extends in the opposite direction and is coupled to a supply voltage. In this manner, current from the supply voltage source flows through the gate resistor before flowing through the gate electrode.

In some embodiments, for example, a first region for the gate electrode may be formed by drilling a trench through the diffusion protection layer (DPL) (e.g., dielectric layer), such that it extends through the DPL and the passivation layer and into the polarization layer. Moreover, the gate electrode may be formed by filling the trench with at least one metal layer. In some embodiments, the metal layer(s) may include aluminum (Al), tantalum (Ta), copper (Cu), nickel (Ni), tungsten (W), platinum (Pt), titanium (Ti), and/or nitrogen (N), such as titanium nitride (TiN) and/or tantalum nitride (TaN), among other examples. For example, in one embodiment, the gate electrode may include a metal layer formed from titanium nitride (TiN). In this manner, since the metal gate electrode extends into the III-N polarization layer, a Schottky barrier is formed at or near an interface of the gate electrode and the polarization layer.

Moreover, a second region for the gate resistor may be formed on or above the DPL layer, such that one end of the gate resistor is in contact with the gate electrode region that extends through the DPL. Moreover, the other end of the gate resistor may be coupled to a supply voltage source. In this manner, current from the supply voltage source flows through the gate resistor before reaching the metal gate electrode. In some embodiments, the gate resistor may be formed from a polycrystalline semiconductor material. For example, the polycrystalline semiconductor material may include a polycrystalline form of silicon (Si), gallium (Ga), and/or nitrogen (N), such as polycrystalline silicon (poly-Si) or polycrystalline gallium nitride (poly-GaN), among other examples.

The flowchart then proceeds to block 416 to form source and drain contacts on the source and drain regions, respectively. In some embodiments, the source and/or drain contacts may be formed from an electrically conductive material such as a metal.

First, one or more interlayer dielectrics (ILD) may be deposited over the existing layers to fill the vacant regions. The ILD layers may be formed using dielectric materials known for their applicability in integrated circuit structures, such as low-k dielectric materials. In some embodiments, the ILD material(s) may include silicon (Si), oxygen (O), fluorine (F), and/or carbon (C), such as oxides of silicon (e.g., silicon dioxide (SiO₂)), doped oxides of silicon, fluorinated oxides of silicon, carbon-doped oxides of silicon, and/or any other low-k dielectric materials and combinations thereof. Next, trenches for the source and drain contacts may be drilled through the ILD layers—above the respective source and drain regions—stopping once the source and drain regions are reached, and the trenches may then be filled with an electrically conductive material such as a metal.

At this point, the flowchart may be complete. In some embodiments, however, the flowchart may restart and/or certain blocks may be repeated. For example, in some embodiments, the flowchart may restart at block 402 to continue fabricating another III-N Schottky transistor with the same or similar design.

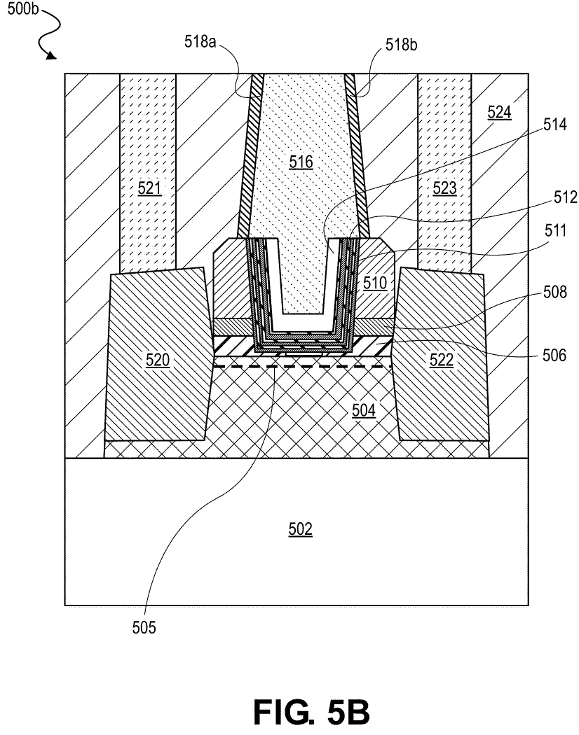

FIGS. 5A-B illustrate examples of a gallium nitride (GaN) metal-oxide-semiconductor (MOS) transistor 500 with a charge-gettering gate dielectric in accordance with certain embodiments. In particular, the charge-gettering gate dielectric is designed to “soak up” trapped charges to prevent them from becoming trapped in other layers (e.g., the channel 504 and/or polarization layer 506), which reduces BTI degradation, as described further below.

In the illustrated embodiment, transistor 500 includes a buffer layer 502, a transistor channel 504, source and drain regions 520, 522, source and drain contacts 521, 523, a polarization layer 506, a passivation layer 508, a diffusion protection layer (DPL) 510, gate dielectric layers 511, 512, gate layers 514, 516, and an inter-layer dielectric (ILD) 524.

The buffer layer 502, which may be formed on or above a silicon substrate (not shown), may include a group III-nitride (III-N) material, such as aluminum gallium nitride (AlGaN). The transistor channel 504 is formed on or above the buffer layer and may also include a III-N material, such as gallium nitride (GaN). In this manner, the AlGaN buffer layer 502 is between the GaN channel 504 and the Si substrate and serves as a buffer separating those layers.

The source region 520 and the drain region 522 are formed on opposite ends of the channel 504, such that they are coupled together via the channel 504. Moreover, the source and drain regions 520, 522 may be formed from a III-N material, such as indium gallium nitride (e.g., N+ InₓGa₁₋ₓN, where x is between 0 and 0.3 and the dopant is Si).

The source and drain contacts 521, 523 are formed on or above above—and in contact with—the respective source and drain regions 520, 522. Moreover, the source and drain contacts 521, 523 may include an electrically conductive material, such as a metal.

The polarization layer 506 is formed on or above the GaN channel 504 and may include a III-N material, such as aluminum gallium nitride (AlGaN). The function of the polarization layer 506 is to induce the formation of a two-dimensional electron gas (2DEG) 505. For example, when the AlGaN polarization layer 506 is deposited on the GaN channel 504, a two-dimensional electron gas (2DEG) 505 forms at or near the interface of the channel 504 and the polarization layer 506.

The passivation layer 508 is formed on or above the polarization layer 506 and may include a dielectric material such as silicon dioxide (SiO₂) or silicon nitride (SiN). The function of the passivation layer 508 is to passivate the surface of the polarization layer 506 (e.g., to protect it from contamination).

The diffusion protection layer (DPL) 510 is formed on or above the passivation layer 508 and may include a dielectric or insulating material, such as silicon nitride (SiN) or silicon dioxide (SiO₂). The function of the DPL 510 is to provide protection from diffusion current caused by the diffusion of charge carriers.

The gate dielectric layers 511, 512 include multiple nested U-shaped layers formed on or in a trench in the diffusion protection layer 510 (which may extend into the passivation layer 508 and/or polarization layer 506). These gate dielectric layers 511, 512 collectively serve as a tunable charge-gettering gate dielectric structure. For example, in some embodiments, gate dielectric layer 511 is a charge-gettering layer that includes a sputtered dielectric material, such as sputtered silicon nitride (SiN) and/or sputtered aluminum nitride (AlN). Moreover, in some embodiments, gate dielectric layer 512 is an insulating dielectric material, such as hafnium oxide (HfO), hafnium zirconium oxide (HfZrO), aluminum oxide (AlO), silicon-rich silicon nitride (SiN), and/or a material such as silicon oxynitride (SiON) with varying oxygen content. Alternatively, or additionally, in some embodiments, gate dielectric layer 512 is a semiconductor dielectric material, such as aluminum gallium nitride (AlGaN), aluminum indium nitride (AlInN), and/or aluminum gallium indium nitride (AlGaInN). In this manner, the gate dielectric layers 511, 512 soak up trapped charges (analogous to a sponge), which prevents the charges from becoming trapped in other layers, such as the channel 504 and/or polarization layer 506. Thus, by preventing or minimizing the trapped charges, BTI degradation is reduced.

In the embodiment shown in FIG. 5A, transistor 500a includes one charge-gettering layer 511 and one semiconductor dielectric layer 512. In this manner, the thickness of each layer 511, 512 may be adjusted or tuned to achieve the desired charge-gettering effect.

In the embodiment shown in FIG. 5B, transistor 500b includes multiple charge-gettering layers 511 and multiple semiconductor dielectric layers 512, and those layers are interleaved or alternating. In this manner, the thickness of the layers 511, 512 can remain constant or fixed, and the number of layers can be adjusted or tuned to achieve the desired charge-gettering effect.

The gate layers 514, 516 collectively form the gate electrode, which is partially surrounded by the gate dielectric structure 511, 512. For example, the gate electrode includes a work function metal layer 514, which is nested within the gate dielectric structure 511, 512, along with a fill metal layer 516 on or above the work function metal layer 514. In some embodiments, the fill metal gate layer 516 has a T-gate shape with upper and lower portions, where the upper portion is wider than the lower portion. The upper portion is coupled to a supply voltage (not shown), while the lower portion is surrounded by the gate dielectric structure 511, 512 and may extend into the diffusion protection layer 510 and/or passivation layer 508. In one embodiment, the work function metal layer 514 may include titanium nitride (TiN) and the fill metal layer 516 may include tungsten (W).

In some embodiments, a pair of gate sidewall spacers 518a,b may also be formed on opposing sides of the gate fill metal 516. The gate spacers 518a,b may include any suitable dielectric material, such as silicon nitride (SiN) and/or silicon carbon nitride (SiCN).

The inter-layer dielectric (ILD) 524 is used to fill the remaining gaps or areas of the transistor 500, and may include any suitable dielectric material, such as silicon dioxide (SiO₂).

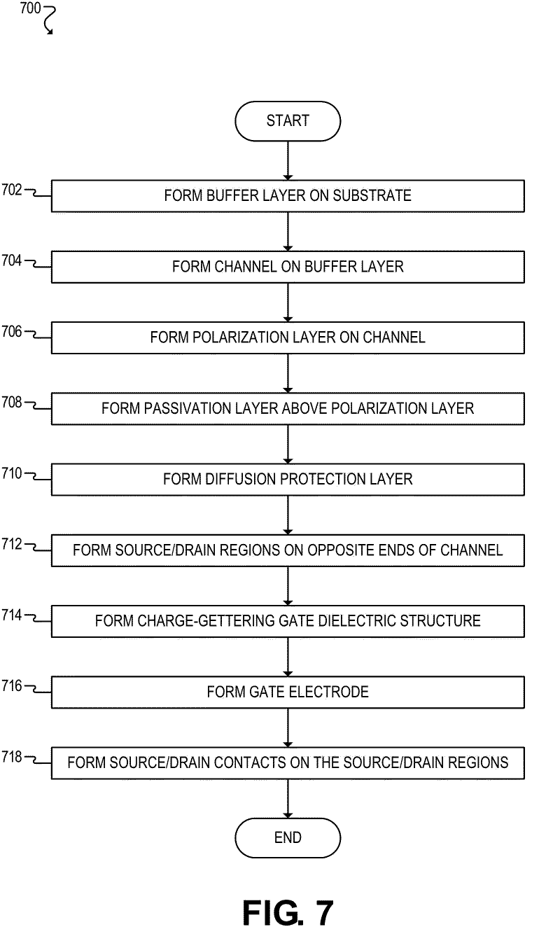

In some embodiments, certain layers of the transistor 500 may be omitted, added, or rearranged. Moreover, certain layers may be formed using materials other than those described above, including the materials described in the example fabrication process 700 of FIG. 7 and in other sections of this disclosure.

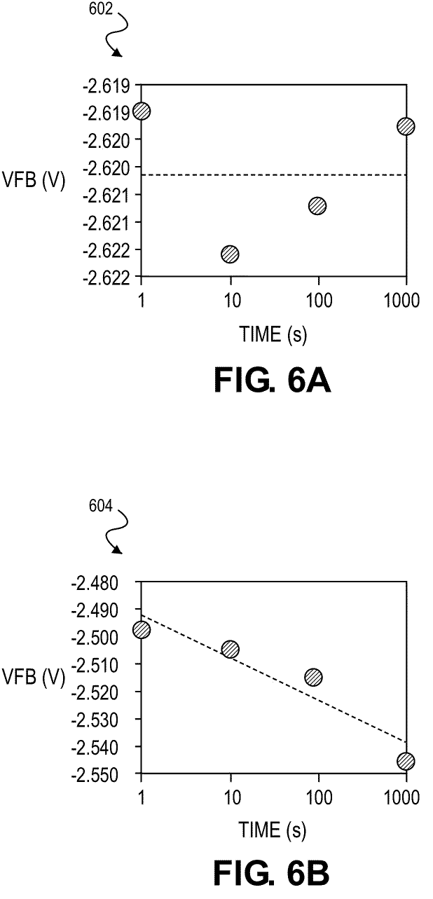

FIGS. 6A-B illustrate graphs 602, 604 of the voltage flat band (VFB) over time for a GaN MOS transistor with a charge-gettering gate dielectric when the charge is switched in (graph 602) and switched out (graph 604). As shown by graph 602, no voltage drift occurs when the charge is switched in. Moreover, as shown by graph 604, only minimal voltage drift occurs when the charge is switched out (e.g., ~45 millivolt (mV) drift over 1000 seconds).

FIG. 7 illustrates a flowchart 700 for fabricating a group III-nitride (III-N) metal-oxide-semiconductor (MOS) transistor with a charge-gettering gate dielectric in accordance with certain embodiments. In some embodiments, for example, flowchart 700 may be used to fabricate the gallium nitride (GaN) MOS charge-gettering gate dielectric transistors of FIGS. 5A-B. It will be appreciated in light of the present disclosure, however, that flowchart 700 is only one example methodology for arriving at the example III-N MOS transistors shown and described throughout this disclosure.

The steps of flowchart 700 may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metalorganic chemical vapor deposition (MOCVD), molecular beam epitaxy (MBE) atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The flowchart begins at block 702 by forming a buffer layer on a substrate. In some embodiments, the substrate may be formed from a material that includes silicon (Si), and the buffer layer may be formed from a group III-nitride (III-N) material. For example, the III-N material may include aluminum (Al), gallium (Ga), and/or nitrogen (N), such as aluminum gallium nitride (AlGaN), among other examples.

The flowchart then proceeds to block 704 to form a channel on the buffer layer. In some embodiments, the channel may be formed from a III-N material. For example, the III-N material may include gallium (Ga) and/or nitrogen (N), such as gallium nitride (GaN), among other examples. In this manner, the channel and the substrate are separated by the buffer layer, and thus the buffer layer serves as a buffer between the channel and the substrate.

The flowchart then proceeds to block 706 to form a polarization layer on the channel. In some embodiments, the polarization layer may be formed from a III-N material. For example, the III-N material may include aluminum (Al), gallium (Ga), and/or nitrogen (N), such as aluminum gallium nitride (AlGaN), among other examples. In this manner, since the polarization layer and channel are both III-N materials, when the polarization layer is deposited on the channel, a two-dimensional electron gas (2DEG) forms at or near the interface of the channel and the polarization layer.

The flowchart then proceeds to block 708 to form a passivation layer on or above the polarization layer. In some embodiments, the passivation layer may be formed from a material that includes silicon (Si) and/or oxygen (O), such as silicon dioxide (SiO₂), among other examples. In this manner, by forming the passivation layer on the polarization layer, the passivation layer passivates the surface of the polarization layer.

The flowchart then proceeds to block 710 to form a diffusion protection layer (DPL) (e.g., a dielectric layer) on or above the passivation layer. In some embodiments, the DPL may be formed from a dielectric or insulating material. For example, the DPL may be formed from a material that includes silicon (Si), nitrogen (N), and/or oxygen (O), such as silicon dioxide (SiO₂) or silicon nitride (SiN), among other examples.

The flowchart then proceeds to block 712 to form source and drain regions on opposite ends of the channel. For example, the source region is formed adjacent to one end of the channel, and the drain region is formed adjacent to another end of the channel. In this manner, the source and drain regions are coupled via the channel. In some embodiments, the source and/or drain regions may be formed from a material that includes indium (In), gallium (Ga), and/or nitrogen (N), such as indium gallium nitride (e.g., N+ InₓGa₁₋ₓN, where x is between 0 and 0.3 and the dopant is Si), among other examples.

The flowchart then proceeds to block 714 to form a charge-gettering gate dielectric structure. In some embodiments, for example, a trench for the gate dielectric structure may be formed or drilled through the diffusion protection layer, passivation layer, and/or polarization layer. Next, the gate dielectric structure may be formed by depositing and etching multiple dielectric layers in the trench, such that each layer has a U-shape and is nested within the preceding layer.

Moreover, the dielectric layers of the gate dielectric structure may include (i) at least one layer of a first dielectric material that includes silicon and/or nitrogen, such as sputtered silicon nitride (SiN), and (ii) at least one layer of a second dielectric material that includes hafnium, oxygen, silicon, and/or nitrogen, such as hafnium oxide (HfO) or silicon-rich silicon nitride (SiN), among other examples. In some embodiments, for example, the first dielectric material may include sputtered silicon nitride (SiN), and the second dielectric material may include hafnium oxide (HfO) or silicon-rich silicon nitride (SiN).

In some embodiments, the gate dielectric structure may include one layer of the first dielectric material and one layer of the second dielectric material. In this manner, the thickness of each layer may be adjusted or tuned to achieve the desired charge-gettering effect.

In other embodiments, the gate dielectric structure may include multiple alternating or interleaved layers of each of the first and second dielectric materials. In this manner, the thickness of the layers can remain constant or fixed, and the number of layers can be adjusted or tuned to achieve the desired charge-gettering effect.

The flowchart then proceeds to block 716 to form a gate electrode. The gate electrode may be formed on or above the gate dielectric structure—such that the gate electrode is at least partially surrounded by the gate dielectric structure—and the gate electrode may include one or more metal layers. In some embodiments, for example, the gate electrode layer may include a stack of at least two metal layers, including at least one work function metal layer and at least one fill metal layer. The work function metal layer may be on or above the gate dielectric structure, and the fill metal layer may be on or above the work function metal layer.

In some embodiments, the work function metal layer and/or fill metal layer may be formed from a material that includes aluminum (Al), tantalum (Ta), copper (Cu), nickel (Ni), tungsten (W), platinum (Pt), titanium (Ti), and/or nitrogen (N), such as titanium nitride (TiN) and/or tantalum nitride (TaN), among other examples. For example, in one embodiment, the work function metal layer may include titanium nitride (TiN) and the fill metal layer may include tungsten (W).

In some embodiments, the gate electrode has a T-gate shape with upper and lower portions, where the upper portion is wider than the lower portion. The upper portion may be coupled to a supply voltage, while the lower portion may be surrounded by the gate dielectric structure and may extend into the diffusion protection layer (DPL) (e.g., dielectric layer) and/or passivation layer. In this manner, trapped charges are soaked up by the gate dielectric structure rather than becoming trapped in other layers, such as the channel and/or polarization layer.

The flowchart then proceeds to block 718 to form source and drain contacts on the source and drain regions, respectively. In some embodiments, the source and/or drain contacts may be formed from an electrically conductive material such as a metal.

First, one or more interlayer dielectrics (ILD) may be deposited over the existing layers to fill the vacant regions. The ILD layers may be formed using dielectric materials known for their applicability in integrated circuit structures, such as low-k dielectric materials. In some embodiments, the ILD material(s) may include silicon (Si), oxygen (O), fluorine (F), and/or carbon (C), such as oxides of silicon (e.g., silicon dioxide (SiO₂)), doped oxides of silicon, fluorinated oxides of silicon, carbon-doped oxides of silicon, and/or any other low-k dielectric materials and combinations thereof. Next, trenches for the source and drain contacts may be drilled through the ILD layers—above the respective source and drain regions—stopping once the source and drain regions are reached, and the trenches may then be filled with an electrically conductive material such as a metal.

At this point, the flowchart may be complete. In some embodiments, however, the flowchart may restart and/or certain blocks may be repeated. For example, in some embodiments, the flowchart may restart at block 702 to continue fabricating another III-N MOS transistor with the same or similar design.

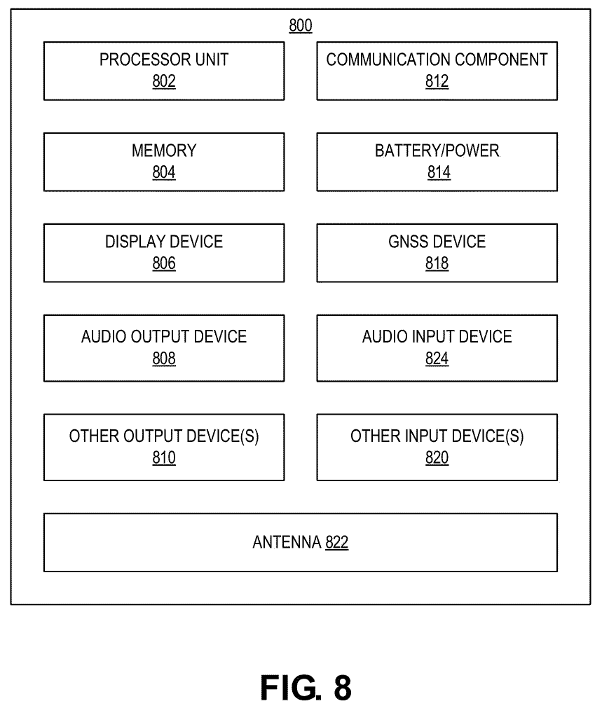

FIG. 8 illustrates a block diagram of an example electrical device 800 that may include one or more of the embodiments disclosed herein. For example, any suitable ones of the components of the electrical device 800—such as processor units 802, memory 804, communication components 812 (e.g., network interface controllers, RF front-end circuits)— may include one or more of the group III-nitride (III-N) transistors described herein (e.g., GaN Schottky transistors with a poly-gate and/or GaN MOS transistors with a charge-gettering gate dielectric). A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. In some embodiments, the communication component 812 may include a radiofrequency (RF) front-end circuit. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications. In some embodiments, the communication component 812 may include a network interface controller.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include other output device(s) 810 (or corresponding interface circuitry, as discussed above). Examples of the other output device(s) 810 may include an audio codec, a video codec, a printer, a wired or wireless transmitter for providing information to other devices, or an additional storage device.

The electrical device 800 may include other input device(s) 820 (or corresponding interface circuitry, as discussed above). Examples of the other input device(s) 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

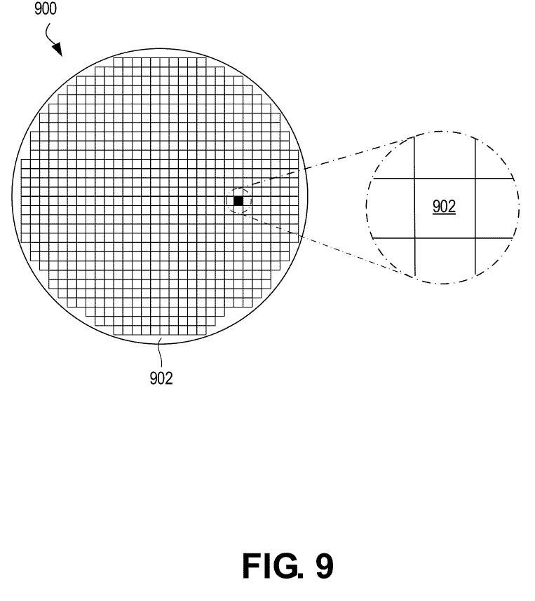

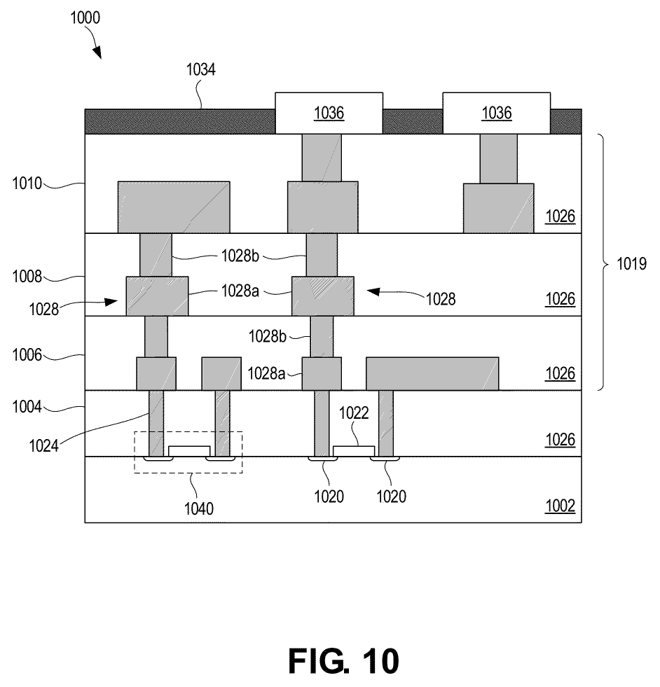

FIG. 9 is a top view of a wafer 900 and dies 902 that may be included in any of the embodiments disclosed herein. The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may be any of the dies disclosed herein. The die 902 may include one or more transistors (e.g., the GaN Schottky poly-gate transistors 100 of FIG. 1, the GaN MOS charge-gettering transistors 500a-b of FIGS. 5A-B, and/or the transistors 1040 of FIG. 10), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 802 of FIG. 8) or other logic that is configured to store information in the memory devices or execute instructions stored in the memory array. Various ones of the microelectronic assemblies disclosed herein may be manufactured using a die-to-wafer assembly technique in which some dies are attached to a wafer 900 that include others of the dies, and the wafer 900 is subsequently singulated.

FIG. 10 is a cross-sectional side view of an integrated circuit device 1000 that may be included in any of the embodiments disclosed herein (e.g., in any of the dies). One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non- planar transistors may include FinFET transistors, such as double-gate transistors or tri-gate transistors, and wrap-around or all-around gate transistors, such as nanoribbon, nanosheet, or nanowire transistors.

Returning to FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page from the perspective of FIG. 10. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components. The conductive contacts 1036 may serve as any of the conductive contacts described throughout this disclosure.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036. These additional conductive contacts may serve as any of the conductive contacts described throughout this disclosure.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. These additional conductive contacts may serve as any of the conductive contacts described throughout this disclosure. In some embodiments, TSVs extending through the substrate can be used for routing power and ground signals from conductive contacts on the opposite side of the integrated circuit device 1000 from the conductive contacts 1036 to the transistors 1040 and any other components integrated into the die 1000, and the metallization stack 1019 can be used to route I/O signals from the conductive contacts 1036 to transistors 1040 and any other components integrated into the die 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

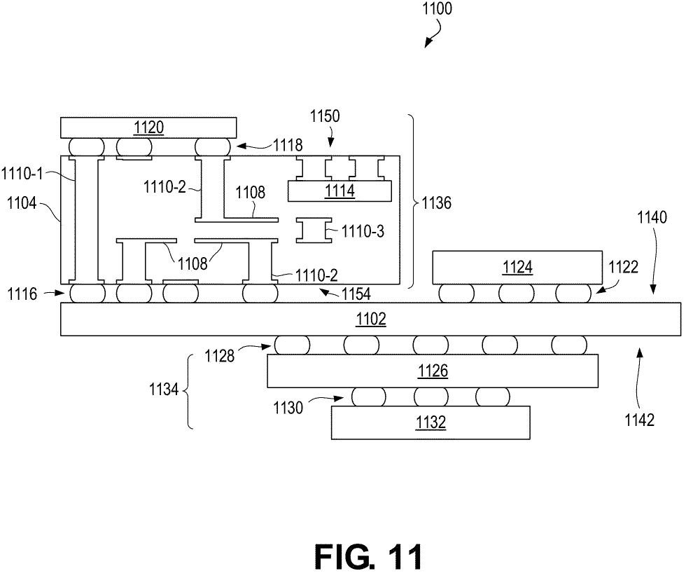

FIG. 11 is a cross-sectional side view of an integrated circuit device assembly 1100 that may include any of the embodiments disclosed herein. In some embodiments, the integrated circuit device assembly 1100 may be a microelectronic assembly. The integrated circuit device assembly 1100 includes a number of components disposed on a circuit board 1102 (which may be a motherboard, system board, mainboard, etc.). The integrated circuit device assembly 1100 includes components disposed on a first face 1140 of the circuit board 1102 and an opposing second face 1142 of the circuit board 1102; generally, components may be disposed on one or both faces 1140 and 1142. Any of the integrated circuit components discussed below with reference to the integrated circuit device assembly 1100 may take the form of any suitable ones of the embodiments of the microelectronic assemblies 100 disclosed herein.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The integrated circuit device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1116 may serve as the coupling components illustrated or described for any of the substrate assembly or substrate assembly components described herein, as appropriate.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpacked integrated circuit product that includes one or more integrated circuit dies (e.g., the die 902 of FIG. 9, the integrated circuit device 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1120 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art. In embodiments where the interposer is a non-printed circuit board

The integrated circuit device assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit device assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

### Example Embodiments

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes an apparatus, comprising: a source region; a source contact on the source region; a drain region; a drain contact on the drain region; a channel between the source region and the drain region, wherein the channel comprises gallium and nitrogen; a polarization layer on the channel, wherein the polarization layer comprises a group III-nitride (III-N) material; and a gate structure, comprising: a first region extending into the polarization layer, wherein the first region comprises a metal; and a second region coupled to the first region, wherein the second region comprises a polycrystalline semiconductor material.

Example 2 includes the apparatus of Example 1, wherein the polycrystalline semiconductor material comprises: silicon; or gallium and nitrogen.

Example 3 includes the apparatus of any of Examples 1-2, wherein the metal comprises titanium and nitrogen.

Example 4 includes the apparatus of any of Examples 1-3, wherein the III-N material comprises aluminum, gallium, and nitrogen.

Example 5 includes the apparatus of any of Examples 1-4, wherein the source region or the drain region comprises indium, gallium, and nitrogen.

Example 6 includes the apparatus of any of Examples 1-5, wherein: the first region of the gate structure is a gate electrode; and the second region of the gate structure is a gate resistor, wherein the gate resistor is further coupled to a supply voltage source.

Example 7 includes the apparatus of Example 6, wherein the gate structure is a T-gate, wherein the T-gate comprises a lower portion and an upper portion, wherein the lower portion comprises the gate electrode and the upper portion comprises the gate resistor.

Example 8 includes the apparatus of any of Examples 6-7, further comprising: a passivation layer on the polarization layer, wherein the passivation layer comprises silicon and oxygen; and a dielectric layer above the passivation layer, wherein the gate electrode extends through the dielectric layer and the passivation layer and into the polarization layer.

Example 9 includes the apparatus of any of Examples 6-8, further comprising: a Schottky barrier at a first interface of the gate electrode and the polarization layer; and a two-dimensional electron gas at a second interface of the channel and the polarization layer.

Example 10 includes the apparatus of any of Examples 1-9, further comprising: a substrate comprising silicon; and a buffer layer between the substrate and the channel, wherein the buffer layer comprises a second III-N material.

Example 11 includes the apparatus of Example 10, wherein the second III-N material comprises aluminum, gallium, and nitrogen.

Example 12 includes the apparatus of any of Examples 1-11, further comprising a transistor, wherein the transistor comprises the source region, the source contact, the drain region, the drain contact, the channel, the polarization layer, and the gate structure.

Example 13 includes a computing device, comprising: a processor; a radio frequency (RF) front-end circuit; or a network interface controller; wherein the processor, the RF front-end circuit, or the network interface controller comprises one or more transistors, wherein individual transistors comprise: a source region; a source contact on the source region; a drain region; a drain contact on the drain region; a channel between the source region and the drain region, wherein the channel comprises gallium and nitrogen; a polarization layer on the channel, wherein the polarization layer comprises a group III-nitride (III-N) material; and a gate structure, comprising: a first region extending into the polarization layer, wherein the first region comprises a metal; and a second region coupled to the first region, wherein the second region comprises a polycrystalline semiconductor material.

Example 14 includes the computing device of Example 13, wherein the polycrystalline semiconductor material comprises: silicon; or gallium and nitrogen.

Example 15 includes the computing device of any of Examples 13-14, wherein the metal comprises titanium and nitrogen.

Example 16 includes the computing device of any of Examples 13-15, wherein the III-N material comprises aluminum, gallium, and nitrogen.

Example 17 includes the computing device of any of Examples 13-16, wherein the source region or the drain region comprises indium, gallium, and nitrogen.

Example 18 includes the computing device of any of Examples 13-17, wherein: the first region of the gate structure is a gate electrode; and the second region of the gate structure is a gate resistor, wherein the gate resistor is further coupled to a supply voltage source.

Example 19 includes the computing device of Example 18, wherein the gate structure is a T-gate, wherein the T-gate comprises a lower portion and an upper portion, wherein the lower portion comprises the gate electrode and the upper portion comprises the gate resistor.

Example 20 includes the computing device of any of Examples 18-19, further comprising: a passivation layer on the polarization layer, wherein the passivation layer comprises silicon and oxygen; a dielectric layer above the passivation layer, wherein the gate electrode extends through the dielectric layer and the passivation layer and into the polarization layer; a Schottky barrier at a first interface of the gate electrode and the polarization layer; and a two-dimensional electron gas at a second interface of the channel and the polarization layer.

Example 21 includes a method of forming a transistor, comprising: forming a buffer layer on a substrate, wherein the substrate comprises silicon, and wherein the buffer layer comprises a first group III-nitride (III-N) material; forming a channel on the buffer layer, wherein the channel comprises gallium and nitrogen; forming a polarization layer on the channel, wherein the polarization layer comprises a second III-N material; forming a dielectric layer above the polarization layer; forming a source region adjacent to a first end of the channel and a drain region adjacent to a second end of the channel, wherein the first end and the second end are opposite ends of the channel; forming a gate structure, wherein the gate structure comprises: a first region extending through the dielectric layer and into the polarization layer, wherein the first region comprises a metal; and a second region on the dielectric layer and in contact with the first region, wherein the second region comprises a polycrystalline semiconductor material; forming a source contact on the source region; and forming a drain contact on the drain region.

Example 22 includes the method of Example 21, further comprising: forming a passivation layer between the polarization layer and the dielectric layer, wherein the passivation layer comprises silicon and oxygen.

Example 23 includes the method of any of Examples 21-22, wherein the polycrystalline semiconductor material comprises: silicon; or gallium and nitrogen.

Example 24 includes the method of any of Examples 21-23, wherein the metal comprises titanium and nitrogen.

Example 25 includes the method of any of Examples 21-24, wherein: the first III-N material comprises aluminum, gallium, and nitrogen; the second III-N material comprises aluminum, gallium, and nitrogen; the source region comprises indium, gallium, and nitrogen; the drain region comprises indium, gallium, and nitrogen; or the dielectric layer comprises: silicon and nitrogen; or silicon and oxygen.

Example 26 includes an apparatus, comprising: a source region; a source contact on the source region; a drain region; a drain contact on the drain region; a channel between the source region and the drain region, wherein the channel comprises gallium and nitrogen; a gate electrode above the channel, wherein the gate electrode comprises a metal material; and a gate dielectric structure at least partially surrounding the gate electrode, wherein the gate dielectric structure comprises a plurality of layers, wherein the plurality of layers comprises: at least one layer of a first dielectric material, wherein the first dielectric material comprises sputtered silicon and nitrogen; and at least one layer of a second dielectric material, wherein the second dielectric material comprises: hafnium and oxygen; or silicon-rich silicon and nitrogen.

Example 27 includes the apparatus of Example 26, wherein the plurality of layers alternate between the first dielectric material and the second dielectric material.

Example 28 includes the apparatus of Example 27, wherein the plurality of layers further comprises a first plurality of layers of the first dielectric material and a second plurality of layers of the second dielectric material, wherein the first plurality of layers are interleaved with the second plurality of layers.

Example 29 includes the apparatus of any of Examples 26-28, wherein the gate electrode further comprises: a first layer on the gate dielectric structure, wherein the first layer comprises titanium; and a second layer above the first layer, wherein the second layer comprises tungsten.

Example 30 includes the apparatus of any of Examples 26-29, further comprising: a polarization layer on the channel, wherein the polarization layer comprises a group III-nitride (III-N) material; and a two-dimensional electron gas at an interface of the channel and the polarization layer.

Example 31 includes the apparatus of Example 30, wherein the III-N material comprises aluminum, gallium, and nitrogen.

Example 32 includes the apparatus of any of Examples 30-31, further comprising a passivation layer on the polarization layer, wherein the passivation layer comprises silicon and oxygen.

Example 33 includes the apparatus of any of Examples 30-32, further comprising a dielectric layer above the polarization layer, wherein the gate electrode extends into the dielectric layer.

Example 34 includes the apparatus of any of Examples 26-33, wherein the source region or the drain region comprises indium, gallium, and nitrogen.

Example 35 includes the apparatus of any of Examples 26-34, wherein the gate electrode has a T-gate shape, wherein the T-gate shape comprises a lower portion and an upper portion.

Example 36 includes the apparatus of any of Examples 26-35, further comprising: a substrate comprising silicon; and a buffer layer between the substrate and the channel, wherein the buffer layer comprises a second III-N material.

Example 37 includes the apparatus of Example 36, wherein the second III-N material comprises aluminum, gallium, and nitrogen.

Example 38 includes the apparatus of any of Examples 26-37, further comprising a transistor, wherein the transistor comprises the source region, the source contact, the drain region, the drain contact, the channel, the gate electrode, and the gate dielectric structure.

In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure. However, the order of description should not be construed to imply that these operations are necessarily order dependent. In particular, these operations may not be performed in the order of presentation.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

As used herein, the term “circuitry” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

1. An apparatus, comprising:
a source region;
a source contact on the source region;
a drain region;
a drain contact on the drain region;
a channel between the source region and the drain region, wherein the channel comprises gallium and nitrogen;
a polarization layer on the channel, wherein the polarization layer comprises a group III-nitride (III-N) material; and
a gate structure, comprising:
a first region extending into the polarization layer, wherein the first region comprises a metal; and
a second region coupled to the first region, wherein the second region comprises a polycrystalline semiconductor material.

2. The apparatus of claim 1, wherein the polycrystalline semiconductor material comprises:
silicon; or
gallium and nitrogen.

3. The apparatus of claim 1, wherein the metal comprises titanium and nitrogen.

4. The apparatus of claim 1, wherein the III-N material comprises aluminum, gallium, and nitrogen.

5. The apparatus of claim 1, wherein the source region or the drain region comprises indium, gallium, and nitrogen.

6. The apparatus of claim 1, wherein:
the first region of the gate structure is a gate electrode; and
the second region of the gate structure is a gate resistor, wherein the gate resistor is further coupled to a supply voltage source.

7. The apparatus of claim 6, wherein the gate structure is a T-gate, wherein the T-gate comprises a lower portion and an upper portion, wherein the lower portion comprises the gate electrode and the upper portion comprises the gate resistor.

8. The apparatus of claim 6, further comprising:
a passivation layer on the polarization layer, wherein the passivation layer comprises silicon and oxygen; and
a dielectric layer above the passivation layer, wherein the gate electrode extends through the dielectric layer and the passivation layer and into the polarization layer.

9. The apparatus of claim 6, further comprising:
a Schottky barrier at a first interface of the gate electrode and the polarization layer; and
a two-dimensional electron gas at a second interface of the channel and the polarization layer.

10. The apparatus of claim 1, further comprising:
a substrate comprising silicon; and
a buffer layer between the substrate and the channel, wherein the buffer layer comprises a second III-N material.

11. The apparatus of claim 10, wherein the second III-N material comprises aluminum, gallium, and nitrogen.

12. The apparatus of claim 1, further comprising a transistor, wherein the transistor comprises the source region, the source contact, the drain region, the drain contact, the channel, the polarization layer, and the gate structure.

13. A computing device, comprising:
a processor;
a radio frequency (RF) front-end circuit; or
a network interface controller;
wherein the processor, the RF front-end circuit, or the network interface controller comprises one or more transistors, wherein individual transistors comprise:
a source region;
a source contact on the source region;
a drain region;
a drain contact on the drain region;
a channel between the source region and the drain region, wherein the channel comprises gallium and nitrogen;
a polarization layer on the channel, wherein the polarization layer comprises a group III-nitride (III-N) material; and
a gate structure, comprising:
a first region extending into the polarization layer, wherein the first region comprises a metal; and
a second region coupled to the first region, wherein the second region comprises a polycrystalline semiconductor material.

14. The computing device of claim 13, wherein the polycrystalline semiconductor material comprises:
silicon; or
gallium and nitrogen.

15. The computing device of claim 13, wherein the metal comprises titanium and nitrogen.

16. The computing device of claim 13, wherein the III-N material comprises aluminum, gallium, and nitrogen.

17. The computing device of claim 13, wherein the source region or the drain region comprises indium, gallium, and nitrogen.

18. The computing device of claim 13, wherein:
the first region of the gate structure is a gate electrode; and
the second region of the gate structure is a gate resistor, wherein the gate resistor is further coupled to a supply voltage source.

19. The computing device of claim 18, wherein the gate structure is a T-gate, wherein the T-gate comprises a lower portion and an upper portion, wherein the lower portion comprises the gate electrode and the upper portion comprises the gate resistor.

20. The computing device of claim 18, further comprising:
a passivation layer on the polarization layer, wherein the passivation layer comprises silicon and oxygen;
a dielectric layer above the passivation layer, wherein the gate electrode extends through the dielectric layer and the passivation layer and into the polarization layer;
a Schottky barrier at a first interface of the gate electrode and the polarization layer; and
a two-dimensional electron gas at a second interface of the channel and the polarization layer.

21. A method of forming a transistor, comprising:
’forming a buffer layer on a substrate, wherein the substrate comprises silicon, and wherein the buffer layer comprises a first group III-nitride (III-N) material;
forming a channel on the buffer layer, wherein the channel comprises gallium and nitrogen;
forming a polarization layer on the channel, wherein the polarization layer comprises a second III-N material;
forming a dielectric layer above the polarization layer;
forming a source region adjacent to a first end of the channel and a drain region adjacent to a second end of the channel, wherein the first end and the second end are opposite ends of the channel;
forming a gate structure, wherein the gate structure comprises:
a first region extending through the dielectric layer and into the polarization layer, wherein the first region comprises a metal; and
a second region on the dielectric layer and in contact with the first region, wherein the second region comprises a polycrystalline semiconductor material;
forming a source contact on the source region; and
forming a drain contact on the drain region.

22. The method of claim 21, further comprising:
forming a passivation layer between the polarization layer and the dielectric layer, wherein the passivation layer comprises silicon and oxygen.

23. The method of claim 21, wherein the polycrystalline semiconductor material comprises:
silicon; or
gallium and nitrogen.

24. The method of claim 21, wherein the metal comprises titanium and nitrogen.

25. The method of claim 21, wherein:
the first III-N material comprises aluminum, gallium, and nitrogen;
the second III-N material comprises aluminum, gallium, and nitrogen;
the source region comprises indium, gallium, and nitrogen;
the drain region comprises indium, gallium, and nitrogen; or
the dielectric layer comprises:
silicon and nitrogen; or
silicon and oxygen.
